(19) United States
(12) Patent Application Publication
(10) Pub. No.: US 2006/0102888 A1
(43) Pub. Date: May 18, 2006

(54) Semiconductor substrate and method of fabricating the same

(75) Inventors: Hans S. Cho, Seoul (KR); Wenxu Xianyu, Yongin-si (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electronics Co., Ltd., Suwon-si (KR)

(21) Appl. No.: 11/270,629

(22) Filed: Nov. 10, 2005

(30) Foreign Application Priority Data
Nov. 12, 2004 (KR) 10-2004-0092334
Mar. 18, 2005 (KR) 10-2005-0022534

(51) Int. Cl. H01L 31/109

(52) U.S. Cl. 257/19

(57) ABSTRACT

A semiconductor substrate and a method of fabricating the same are provided. The semiconductor substrate includes: a Si substrate; a SiO₂ layer having a predetermined width formed on the Si substrate; a SiGe layer having a first end portion and a second end portion at both sides and formed on the Si substrate and the SiO₂ layer to bury the SiO₂ layer, and generated from both the first and second ends using epitaxial growth; and strained Si layers, in which lattice mismatch of Si is induced, formed on the SiGe layer above the SiO₂ layer using epitaxial growth.

This application claims the benefit of Korean Patent Application Nos. 10-2004-0092334 and 10-2005-0022534, filed on Nov. 12, 2004 and 18 Mar. 2005, in the Korean Intellectual Property Office, the disclosure of which is incorporated herein in its entirety by reference.

### BACKGROUND OF THE DISCLOSURE

1. Field of the Disclosure

The present disclosure relates to a semiconductor substrate and a method of fabricating the same, and more particularly, to a semiconductor substrate having low parasitic capacitance and high carrier mobility and a method of fabricating the same.

2. Description of the Related Art

In the semiconductor industry, to obtain a semiconductor substrate structure having high carrier mobility in conventional CMOS applied apparatuses, a hetero structure based on strained Si has been typically used. In the conventional methods, the strained Si layer is grown on a thick (about 1-5 μm) relaxed SiGe layer to realize such a hetero structure.

However, when the thick SiGe layer is used in the semiconductor substrate, several problems occur. First, the thick SiGe layer cannot be easily integrated into the conventional CMOS technology based on Si. Second, a defect density including threading dislocation (TD) and misfit dislocation is about 10⁵-10⁸ defects/cm, which is of a too high value for a practical, very large scale integration (VLSI) application apparatus. Third, since a structure of the conventional semiconductor substrate excludes selective growth of a SiGe layer in itself, it is difficult or even impossible to integrate a device comprising strained Si, relaxed Si, and SiGe material on the substrate. Thus, even when the conventional semiconductor substrate has SiGe on insulator (SGOI), the effects of the SGOI, for example, of decreasing parasitic capacitance and increasing carrier mobility, cannot be obtained owing to the thick SiGe layer.

A conventional method of fabricating the semiconductor substrate includes many processes, such as a transfer process and a bonding process, etc., which complicates the method. Further, the method requires a SOI substrate, thereby increasing production costs.

U.S. Patent Publication No. 0068102 describes a method of fabricating a high quality relaxed SGOI. In this method, a barrier layer resistant to Ge diffusion, for example, a SOI substrate, is required. However, this SOI substrate is expensive, thus increasing production costs.

### SUMMARY OF THE DISCLOSURE

The present invention may provide a semiconductor substrate having low parasitic capacitance and high carrier mobility and a method of fabricating the same.

The present invention also may provide a method of easily fabricating a semiconductor substrate having a structure in which strained Si layers are formed on a SiGe on insulator (SGOI) substrate in a simplified manner.

According to an aspect of the present invention, there is provided a semiconductor substrate including: a Si substrate; a SiO₂ layer having a predetermined width formed on the Si substrate; a SiGe layer having a first end portion and a second end portion at both sides and formed on the Si substrate and the SiO₂ layer to bury the SiO₂ layer, and generated from both the first and second ends using epitaxial growth; and strained Si layers, in which lattice mismatch of Si is induced, formed on the SiGe layer above the SiO₂ layer using epitaxial growth.

Here, a boundary region at which crystal grains grown from the first and second end portions, respectively, meet each other, is formed on the SiGe layer. The strained Si layers are formed on a portion of the SiGe layer in which the boundary region is not formed.

According to another aspect of the present invention, there is provided a method of fabricating a semiconductor substrate. The method includes: preparing a Si substrate; forming a SiO₂ layer having a predetermined thickness on the Si substrate; patterning the SiO₂ layer to a predetermined width; forming a SiGe layer on the Si substrate and the SiO₂ layer; annealing the SiGe layer formed on the SiO₂ layer; and forming Si layers on the SiGe layer above the SiO₂ layer to induce lattice mismatch of Si, thereby obtaining strained Si layers.

In the forming the SiGe layer, the SiGe layer has first portions which are formed on the substrate and a second portion which is formed on the SiO₂ layer, one of the first portions meeting the second portion at a first boundary region and the other first portion meeting the second portion at a second boundary region. The first portions are formed using epitaxial growth, and the second portion is formed to an amorphous structure or a polycrystalline structure.

In the annealing, the second portion including the first and second boundary regions is crystallized, and the crystallization starts from the first and second boundary regions, respectively, using lateral epitaxial growth. The annealing is performed using a laser beam.

In addition, in a third boundary region at which crystal grains grown from the first and second boundary regions, respectively, meet each other, is formed in the second portion, and the strained Si layers are formed on a portion of the SiGe layer in which the third boundary region is not formed.

According to another aspect of the present invention, there is provided a method of fabricating a semiconductor substrate, including: preparing a Si substrate; forming a SiO₂ layer having a predetermined thickness on the Si substrate; patterning the SiO₂ layer to a predetermined width; forming a Si layer on the Si substrate and the SiO₂ layer; annealing the Si layer formed on the SiO₂ layer; doping the entire Si layer with a Ge ion; annealing the doped Si layer to form a SiGe layer; and forming Si layers on the SiGe layer above the SiO₂ layer to induce lattice mismatch of Si, thereby obtaining strained Si layers.

In the forming the Si layer, the Si layer has first portions which are formed on the substrate and a second portion which is formed on the SiO₂ layer, one of the first portions meeting the second portion at a first boundary region and the other first portion meeting the second portion at a second boundary region. The first portions are formed using epitaxial growth, and the second portion is formed to an amorphous structure or a polycrystalline structure.

In the annealing the doped Si layer, the second portion including the first and second boundary regions is crystallized, and the crystallization starts from the first and second boundary regions, respectively, using lateral epitaxial growth. The annealing is performed using a laser beam.

In addition, a third boundary region at which crystal grains grown from the first and second boundary regions, respectively, meet each other, is formed in the second portion, and in the forming the SiGe layer and the forming the strained Si layers, the SiGe layer has the third boundary region. The strained Si layers are formed on a portion of the SiGe layer in which the third boundary region is not formed.

The doping with the Ge ion is performed using an ion implanter, and the annealing the doped Si layer is performed using a laser beam apparatus or a low temperature apparatus.

### BRIEF DESCRIPTION OF THE DRAWINGS

The above and other features and advantages of the present invention are described in detailed exemplary embodiments thereof with reference to the attached drawings in which:

FIG. 1 is a cross-sectional view of a semiconductor substrate according to an embodiment of the present invention;

FIGS. 2A through 2F illustrate a method of fabricating a semiconductor substrate according to an embodiment of the present invention; and

FIGS. 3A through 3I illustrate a method of fabricating a semiconductor substrate according to another embodiment of the present invention.

### DETAILED DESCRIPTION OF EXEMPLARY EMBODIMENTS

Hereinafter, a semiconductor substrate and a method of fabricating the same according to embodiments of the present invention will be described in more detail with reference to the attached drawings.

FIG. 1 is a cross-sectional view of a semiconductor substrate according to an embodiment of the present invention.

Referring to FIG. 1, a SiO₂ layer 12 having a predetermined width is formed on a Si substrate 10 and a SiGe layer 40 is formed on the Si substrate 10 and the SiO₂ layer 12 to bury the SiO₂ layer 12. The Si substrate 10 is made of single crystals.

The SiGe layer 40 has a first end portion 40a and a second end portion 40b at both sides. The SiGe layer 40 has a relaxed crystal structure which is formed from the first and second end portions 40a and 40b using lateral epitaxial growth. A boundary region 42 at which crystal grains grown from the first and second end portions 40a and 40b, respectively, meet each other, is formed on the SiGe layer 40. Strained Si layers 50 are formed on the SiGe layer 40 above the SiO₂ layer 12 using epitaxial growth. The strained Si layers 50 may be formed on a portion of the SiGe layer 40 in which the boundary region 42 is not formed.

SiGe has a greater lattice constant than Si. When Si is epitaxially grown on a relaxed SiGe layer, the Si keeps a coherence relation with the relaxed SiGe layer, and thus, tensile stress is applied to an internal lattice of the Si. As a result, the Si has higher carrier mobility than relaxed Si.

The semiconductor substrate according to an embodiment of the present invention has the structure in which strained Si layers are formed on a SiGe on insulator (SGOI). Such a semiconductor substrate has low parasitic capacitance and high carrier mobility. Further, cross-talk between devices installed on the semiconductor substrate is reduced. Thus, the semiconductor substrate according to an embodiment of the present invention can be used as a base substrate for a next generation, high performance transistor device which operates at high speed and low electrical power consumption.

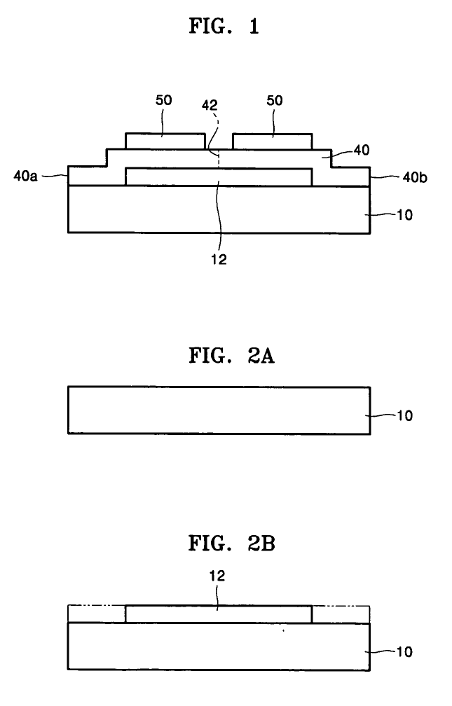

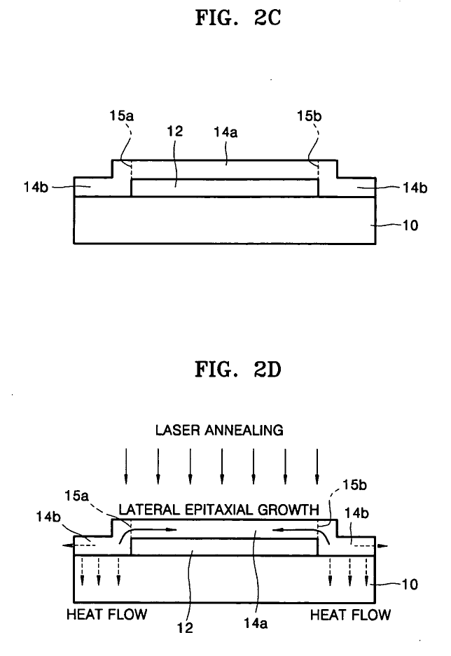

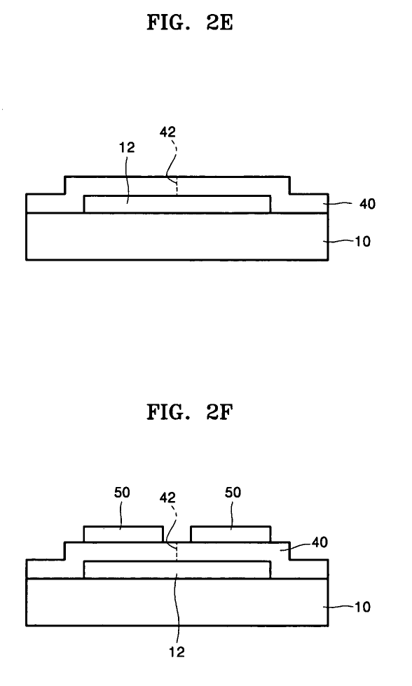

FIGS. 2A through 2F illustrate a method of fabricating a semiconductor substrate according to an embodiment of the present invention.

Referring to FIGS. 2A and 2B, a single crystal Si substrate 10 is prepared and a SiO₂ layer 12 having a predetermined thickness is formed on the Si substrate 10. Then, the SiO₂ layer 12 is patterned to a predetermined width.

Referring to FIG. 2C, a SiGe layer 14a and 14b is formed on the Si substrate 10 and the SiO₂ layer 12. The SiGe layer 14a and 14b has first portions 14b which are formed on the substrate 10 and a second portion 14a which is formed on the SiO₂ layer 12, one of the first portions 14b meeting the second portion 14a at a first boundary region 15a and the other first portion 14b meeting the second portion 14a at a second boundary region 15b. The first portions 14b are formed on the single crystal Si substrate 10 using epitaxial growth. The second portion 14a is formed on the SiO₂ layer 12, which has an amorphous structure, to have an amorphous structure or a polycrystalline structure.

Referring to FIGS. 2D and 2E, the second portion 14a is annealed. In the annealing, the second portion 14a is crystallized. The crystallization starts from the first and second boundary regions 15a and 15b, respectively, using lateral epitaxial growth. Due to the crystallization, the second portion 14a has a relaxed crystal structure. A third boundary region 42 at which crystal grains grown from the first and second boundary regions 15a and 15b, respectively, meet each other, is formed in the second portion 14a. The annealing may be performed using a laser beam.

Referring to FIG. 2F, strained Si layers 50 are formed on the relaxed SiGe layer 40 above the SiO₂ layer 12 using epitaxial growth. Lattice mismatch of the Si is induced on the relaxed SiGe layer 40 to form the strained Si layers 50. The strained Si layers 50 may be formed on a portion of the SiGe layer 40 in which the third boundary region 42 is not formed.

SiGe has a greater lattice constant than Si. When Si is epitaxially grown on a relaxed SiGe layer, the Si keeps a coherence relation with the relaxed SiGe layer, and thus, tensile stress is applied to an internal lattice of the Si. As a result, the Si has higher carrier mobility than relaxed Si.

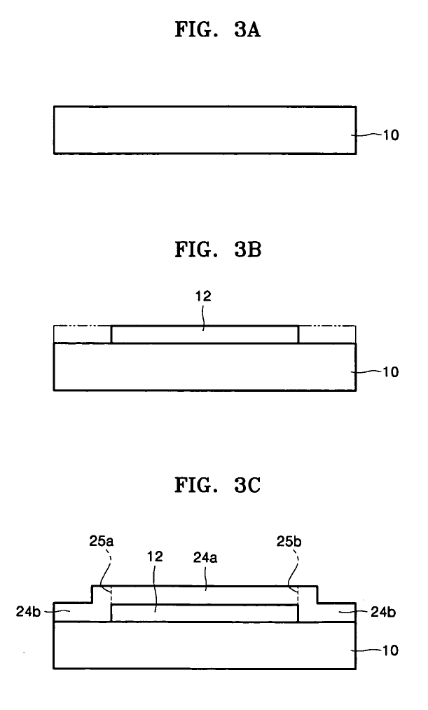

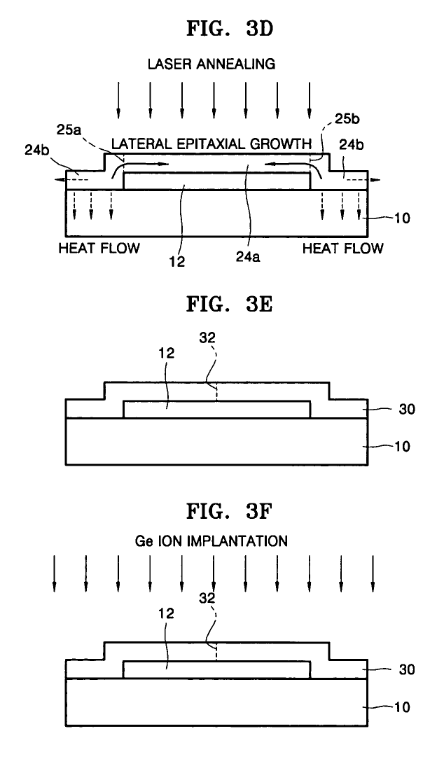

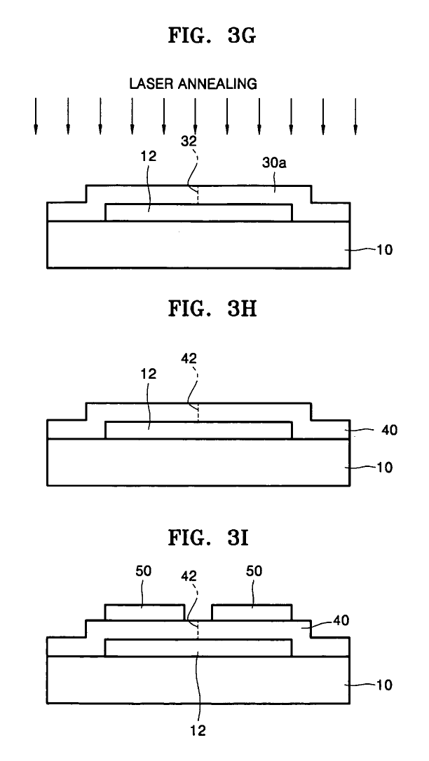

FIGS. 3A through 31 illustrate a method of fabricating a semiconductor substrate according to another embodiment of the present invention.

Referring to FIGS. 3A and 3B, a single crystal Si substrate 10 is prepared and a SiO₂ layer 12 having a predetermined thickness is formed on the Si substrate 10. Then, the SiO₂ layer 12 is patterned to a predetermined width.

Referring to FIG. 3C, a SiGe layer 24a and 24b is formed on the Si substrate 10 and the SiO₂ layer 12. The SiGe layer 24a and 24b has first portions 24b which are formed on the substrate 10, a second portion 24a which is formed on the SiO₂ layer 12, one of the first portions 24b meeting the second portion 24a at a first boundary region 25a and the other first portion 24b meeting the second portion 24a at a second boundary region 25b. The first portions 24b are formed on the single crystal Si substrate 10 using epitaxial growth. The second portion 24a is formed on the SiO₂ layer 12, which has an amorphous structure, to have an amorphous structure or a polycrystalline structure.

Referring to FIGS. 3D and 3E, the second portion 24a is annealed. In the annealing, the second portion 24a is crystallized. The crystallization starts from the first and second boundary regions 25a and 25b, respectively, using lateral epitaxial growth. Due to the crystallization, the second portion 24a has a relaxed crystal structure. A third boundary region 32 at which crystal grains grown from the first and second boundary regions 25a and 25b, respectively, meet each other, is formed in the second portion 24a. The annealing is performed using a laser beam.

Referring to FIGS. 3F through 3H, the entire Si layer 30 is doped with a Ge ion and the doped Si layer 30a is annealed to be changed into a SiGe layer 40. In this case, a third boundary region 42 remains as it was, in the SiGe layer 40 and the SiGe layer 40 has a relaxed crystal structure. The doping with the Ge ion may be performed using an ion implanter. The annealing of the doped Si layer 30a may be performed using a laser beam apparatus or a low temperature apparatus.

Referring to FIG. 3I, strained Si layers 50 are formed on the relaxed SiGe layer 40 above the SiO₂ layer 12 using epitaxial growth. Lattice mismatch of the Si is induced on the relaxed SiGe layer 40 to form the strained Si layers 50. The strained Si layers 50 may be formed on a portion of the SiGe layer 40 in which the third boundary region 42 is not formed.

According to the method of fabricating a semiconductor substrate according an embodiment of the present invention, the semiconductor substrate having the structure in which the strained Si layers are formed on the SGOI substrate can be easily fabricated in a simplified manner. Further, the expensive SOI substrate is not used in the semiconductor substrate, and thus, production costs can be reduced.

### EXAMPLE

First, a SiO₂ layer is formed to a thickness of approximately 500-1000 Å on a single crystal Si substrate using plasma enhanced chemical vapor deposition (PECVD) or low-pressure chemical vapor deposition (LPCVD), etc. The deposition was performed at an internal chamber temperature of approximately 450 C° for 10 minutes.

Then, the SiO₂ layer was patterned to a width of approximately 4-20 μm. Next, a SiGe layer was formed on the Si substrate and the SiO₂ layer using ultra high vacuum chemical vapor deposition (UHV-CVD). In this case, epi-SiGe was formed on the single crystal Si substrate and simultaneously SiGe having an amorphous structure was formed on the SiO₂ layer. The deposition was performed at an internal chamber temperature of approximately 500-800 C° or higher for 30-100 minutes.

Subsequently, the SiGe having the amorphous structure was crystallized by annealing said SiGe using an excimer laser. An energy density of the laser beam was approximately 400-1000 mJ/cm². Next, strained Si layers were formed on the crystallized SiGe layer using UHV-CVD. The deposition was performed at an internal chamber temperature of approximately 500-800 C° or higher for 30-100 minutes.

The semiconductor substrate according to an embodiment of the present invention has the structure in which strained Si layers are formed on an SGOI. Such a semiconductor substrate has low parasitic capacitance and high carrier mobility. Further, cross-talk between devices installed on the semiconductor substrate is reduced. Thus, when the semiconductor substrate according to an embodiment of the present invention is used as a base substrate for a semiconductor device, the semiconductor device can operate at high speed and low electrical power consumption and have an improved switching property.

According to the method of fabricating a semiconductor substrate according an embodiment of the present invention, the semiconductor substrate having the structure in which strained Si layers are formed on the SGOI substrate can be easily fabricated in a simplified manner. Further, the expensive SOI substrate is not used in the semiconductor substrate, and thus, production costs can be reduced.

The semiconductor substrate according to an embodiment of the present invention can be used as a base substrate for a next generation, high performance transistor device which operates at high speed and low electrical power consumption. When the semiconductor substrate and the method of fabricating the same according to embodiments of the present invention are applied to fabrication of a semiconductor memory device and a next generation device, these devices can be effectively fabricated and their performance can be maximized.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor substrate comprising:
a Si substrate;
a SiO₂ layer having a predetermined width formed on the Si substrate;
a SiGe layer having a first end portion and a second end portion at both sides and formed on the Si substrate and the SiO₂ layer to bury the SiO₂ layer, and generated from both the first and second ends using epitaxial growth; and
strained Si layers, in which lattice mismatch of Si is induced, formed on the SiGe layer above the SiO₂ layer using epitaxial growth.

2. The semiconductor substrate of claim 1, wherein a boundary region at which crystal grains grown from the first and second end portions, respectively, meet each other, is formed on the SiGe layer.

3. The semiconductor substrate of claim 2, the strained Si layers are formed on a portion of the SiGe layer in which the boundary region is not formed.

4. A method of fabricating a semiconductor substrate, comprising:
preparing a Si substrate;
forming a SiO₂ layer having a predetermined thickness on the Si substrate;
patterning the SiO₂ layer to a predetermined width;
forming a SiGe layer on the Si substrate and the SiO₂ layer;
annealing the SiGe layer formed on the SiO₂ layer; and
forming Si layers on the SiGe layer above the SiO₂ layer to induce lattice mismatch of Si, thereby obtaining strained Si layers.

5. The method of claim 4, wherein in the forming the SiGe layer, the SiGe layer has first portions which are formed on the substrate and a second portion which is formed on the SiO₂ layer, one of the first portions meeting the second portion at a first boundary region and the other first portion meeting the second portion at a second boundary region.

6. The method of claim 5, wherein the first portions are formed using epitaxial growth.

7. The method of claim 5, wherein the second portion is formed to an amorphous structure or a polycrystalline structure.

8. The method of claim 5, wherein in the annealing, the second portion including the first and second boundary regions is crystallized.

9. The method of claim 8, wherein the crystallization starts from the first and second boundary regions, respectively, using lateral epitaxial growth.

10. The method of claim 9, wherein a third boundary region at which crystal grains grown from the first and second boundary regions, respectively, meet each other, is formed in the second portion.

11. The method of claim 10, wherein the strained Si layers are formed on a portion of the SiGe layer in which the third boundary region is not formed.

12. The method of claim 4, wherein the annealing is performed using a laser beam.

13. A method of fabricating a semiconductor substrate, comprising:
preparing a Si substrate;
forming a SiO₂ layer having a predetermined thickness on the Si substrate;
patterning the SiO₂ layer to a predetermined width;
forming a Si layer on the Si substrate and the SiO₂ layer;
annealing the Si layer formed on the SiO₂ layer;
doping the entire Si layer with a Ge ion;
annealing the doped Si layer to form a SiGe layer; and
forming Si layers on the SiGe layer above the SiO₂ layer to induce lattice mismatch of Si, thereby obtaining strained Si layers.

14. The method of claim 13, wherein in the forming the Si layer, the Si layer has first portions which are formed on the substrate and a second portion which is formed on the SiO₂ layer, one of the first portions meeting the second portion at a first boundary region and the other first portion meeting the second portion at a second boundary region.

15. The method of claim 14, wherein the first portions are formed using epitaxial growth.

16. The method of claim 14, wherein the second portion is formed to an amorphous structure or a polycrystalline structure.

17. The method of claim 14, wherein in the annealing the doped Si layer, the second portion including the first and second boundary regions is crystallized.

18. The method of claim 17, wherein the crystallization starts from the first and second boundary regions, respectively, using lateral epitaxial growth.

19. The method of claim 18, wherein a third boundary region at which crystal grains grown from the first and second boundary regions, respectively, meet each other, is formed in the second portion.

20. The method of claim 19, wherein in the forming the SiGe layer and the forming the strained Si layers, the SiGe layer has the third boundary region.

21. The method of claim 20, wherein the strained Si layers are formed on a portion of the SiGe layer in which the third boundary region is not formed.

22. The method of claim 13, wherein the annealing is performed using a laser beam.

23. The method of claim 13, wherein the doping with the Ge ion is performed using an ion implanter.

24. The method of claim 13, wherein the annealing the doped Si layer is performed using a laser beam apparatus or a low temperature apparatus.
